(19) United States
(12) Patent Application Publication
(10) Pub. No.: US 2025/0079371 A1
(43) Pub. Date: Mar. 6, 2025

(54) SEMICONDUCTOR DIE ASSEMBLIES WITH FLEXIBLE INTERCONNECTS AND ASSOCIATED METHODS AND SYSTEMS

(71) Applicant: Micron Technology, Inc., Boise, ID (US)

(72) Inventors: Christopher Glancey, Boise, ID (US); Shams U. Arifeen, Boise, ID (US); Koustav Sinha, Boise, ID (US); Quang Nguyen, Boise, ID (US)

(21) Appl. No.: 18/954,176

(22) Filed: Nov. 20, 2024

Related U.S. Application Data
(62) Division of application No. 17/674,685, filed on Feb. 17, 2022.

(51) Int. Cl. H01L 23/00

(52) U.S. Cl. CPC H01L 24/13; H01L 24/05; H01L 24/11; H01L 24/16; H01L 2224/0401; H01L 2224/1147; H01L 2224/11901; H01L 2224/13005; H01L 2224/13084; H01L 2224/13147; H01L 2224/16227

(57) ABSTRACT

Semiconductor die assemblies with flexible interconnects, and associated methods and systems are disclosed. The semiconductor die assembly includes a package substrate and a semiconductor die attached to the package substrate through the flexible interconnects. The flexible interconnects include one or more rigid sections and one or more flexible sections, each of which is disposed next to the rigid sections. The flexible sections may include malleable materials with relatively low melting temperatures (e.g., having relatively low modulus at elevated temperatures) such that the flexible interconnects can have reduced flexural stiffness during the assembly process. The malleable materials of the flexible interconnects, through plastic deformation in response to stress generated during the assembly process, may facilitate portions of the flexible interconnects to shift so as to reduce transfer of the stress to other parts of the semiconductor die assembly-e.g., circuitry of the semiconductor die.

### CROSS-REFERENCE TO RELATED APPLICATION(S)

This application is a division of U.S. application Ser. No. 17/674,685, filed Feb. 17, 2022, which is incorporated herein by reference in its entirety.

### TECHNICAL FIELD

The present disclosure generally relates to semiconductor device assemblies, and more particularly relates to semiconductor die assemblies with flexible interconnects and associated methods and systems.

### BACKGROUND

Semiconductor packages typically include one or more semiconductor dies (e.g., memory chips, microprocessor chip, imager chip) mounted on a package substrate and encased in a protective covering. The semiconductor dies include various functional features, such as memory cells, processor circuits, or imager devices, as well as bond pads electrically connected to the functional features. The bond pads are electrically connected to corresponding conductive structures of the package substrate, which are coupled to terminals outside the protective covering such that the semiconductor dies can be connected to higher level circuitry. In certain semiconductor packages, flip-chip bonding technology is used to attach semiconductor dies to the package substrate.

Market pressures continually drive semiconductor manufacturers to reduce the size of die packages to fit within the space constraints of electronic devices, while also pressuring them to increase the functional capability of each package. One approach for increasing the processing power of semiconductor packages without substantially increasing the surface area occupied by the packages is to vertically stack multiple semiconductor dies on top of one another in a single package. In some cases, the semiconductor dies are stacked in a “zig-zag” pattern to provide a space above the bond pads with respect to a semiconductor die overlying above the bond pads. In some semiconductor packages, the thickness of the semiconductor dies are reduced to stack multiple semiconductor dies without increasing overall heights of the semiconductor packages.

### BRIEF DESCRIPTION OF THE DRAWINGS

Many aspects of the present technology can be better understood with reference to the following drawings. The components in the drawings are not necessarily to scale. Instead, emphasis is placed on clearly illustrating the overall features and the principles of the present technology.

FIGS. 1A through 1C illustrate schematic diagrams of a semiconductor die assembly.

FIGS. 2A through 2C illustrate stages of a process for forming flexible interconnects in accordance with embodiments of the present technology.

FIGS. 3A through 3C illustrate stages of a process for forming flexible interconnects in accordance with embodiments of the present technology.

FIGS. 4A and 4B illustrate schematic diagrams of a semiconductor die assembly in accordance with embodiments of the present technology.

FIGS. 5A and 5B illustrate schematic diagrams of a semiconductor die assembly in accordance with embodiments of the present technology.

FIGS. 6A through 6C illustrate schematic diagrams of flexible interconnects in accordance with embodiments of the present technology.

FIG. 7 is a block diagram schematically illustrating a system including a semiconductor die assembly in accordance with embodiments of the present technology.

FIG. 8 is a flowchart of a method of forming a semiconductor device assembly in accordance with embodiments of the present technology

### DETAILED DESCRIPTION

Specific details of several embodiments of semiconductor die assemblies with flexible interconnects, and associated methods and systems are described below. The term “semiconductor device or die” generally refers to a solid-state device that includes one or more semiconductor materials. Examples of semiconductor devices (or dies) include logic devices or dies, memory devices or dies, interface devices or dies, controllers, memory controllers, or processors (e.g., central processing unit (CPU), graphics processing unit (GPU)), field-programmable gate arrays (FPGAs), among others.

Such semiconductor devices or dies may include integrated circuits or components, data storage elements, processing components, and/or other features manufactured on semiconductor substrates (e.g., silicon substrates). Further, the term “semiconductor device or die” can refer to a finished device or to an assembly or other structure at various stages of processing before becoming a finished functional device. Depending upon the context in which it is used, the term “substrate” may include a semiconductor wafer, a semiconductor substrate, a package substrate, an interposer, a semiconductor device or die, or the like. Suitable steps of the methods described herein can be performed with processing steps associated with fabricating semiconductor devices (wafer-level and/or die-level) and/or manufacturing semiconductor packages.

In some semiconductor packages, direct chip attach (DCA) assembly processes (e.g., utilizing flip-chip bonding between a semiconductor die and a package substrate) are used to reduce the footprints of the semiconductor packages. Typical DCA assembly processes include forming conductive pillars on bond pads of a semiconductor die. The conductive pillars may include solder structures at the top portions of the conductive pillars. Subsequently, the semiconductor die with conductive pillars is aligned over a package substrate such that individual conductive pillars are aligned to corresponding substrate bond pads (or conductive bumps) of the package substrate such that the solder structures are in contact with the substrate bond pads.

The aligned semiconductor die and the package substrate are heated to an elevated temperature (e.g., greater than about 220 degrees Celsius), which may be referred to as a reflow process or a mass reflow process. During the reflow process, solder materials of the solder structure can melt to spread across the bonding interface between the conductive pillars and the substrate bond pads to form interconnects (which may also be referred to as joints) connecting the bond pads of the semiconductor die to the substrate bond pads of the package substrate. In some cases, the melted solder materials may partially wrap around the substrate bond pads. After the reflow process, the semiconductor die and the package substrate attached to each other through the interconnects are encapsulated (e.g., using capillary underfill or epoxy mold compound (EMC)) during molding process steps. In some cases, the interconnects may refer to the conductive pillars (including the solder structures). In some cases, the interconnects may refer to the conductive pillars conjoined with (attached to) the substrate bond pads through the solder structures.

During the DCA assembly process for manufacturing semiconductor die packages, the interconnects may experience a variety of stresses, which can lead to defects, cracking, and other yield and/or reliability issues in the final semiconductor die packages. For example, during the reflow process, both the semiconductor die and the package substrate are heated (e.g., above 200° C.) to facilitate bonding between the conductive pillars and the substrate bond pads—e.g., by melting the solder material. While the semiconductor die and the package substrate are cooled down after the reflow process, the interconnects may experience stress due to mismatches in coefficients of thermal expansion (CTEs) between the semiconductor die and the package substrate. Other assembly process steps, such as handling, underfilling, and molding may increase the stress the interconnects experience. The stress can lead to various reliability and/or yield issues in the semiconductor die packages due to adverse effects to circuitry layers having relatively low strength against stress—e.g., cracking or peeling of low-k dielectric layers of the circuitry.

The present technology is expected to mitigate the reliability and/or yield issues associated with the stress during the assembly process by enhancing the compliance of the interconnects (conductive pillars)—e.g., making the interconnects more flexible, malleable, or deformable in response to the variety of stress. Such compliant interconnects (or flexible interconnects) may facilitate accommodating (releasing or relaxing) the stress during the assembly process—e.g., during the cool-down steps following the reflow process steps. The flexible interconnects may reduce transfer of the stress to other parts of the semiconductor die package—e.g., various layers associated with integrated circuitry of the semiconductor die.

Compliant pillar structures in accordance with the present technology include one or more flexible sections with relatively more flexible materials (e.g., relatively low modulus materials, materials with relatively low melting temperatures) disposed next to one or more rigid sections with relatively less flexible materials (e.g., relatively high modulus materials, materials with relatively high melting temperatures). In other words, the flexible sections can be configured to deform in response to less force than the rigid sections. In some embodiments, the materials included in the flexible sections have less modulus values than the modulus values of the materials included in the rigid sections (e.g., less than 100% of the modulus values of the materials included in the rigid sections, less than 75% of those values, less than 67% of those values, less than 50% of those values, less than 33% of those values, less than 25% of those values, less than 10% of those values, or less than 1% of those values, according to various aspects of the present disclosure). In some embodiments, the materials included in the flexible sections have lower melting temperatures than the melting temperatures of the materials included in the rigid sections. In this manner, portions of the compliant pillars can shift or rotate through plastic deformation of the flexible sections in response to the stress—e.g., under surface tension to account for the CTE mismatch strains between the semiconductor die and the package substrate during the cool-down steps. Such compliant pillar structures may be regarded to have reduced flexural stiffness (especially at elevated temperatures during the assembly process) to become flexible (e.g., deformable) in response to the stress.

As used herein, the terms “front,” “back,” “vertical,” “lateral,” “down,” “up,” “top,” “bottom,” “upper,” and “lower” can refer to relative directions or positions of features in the semiconductor device assemblies in view of the orientation shown in the Figures. For example, “upper” or “uppermost” can refer to a feature positioned closer to the top of a page than another feature. These terms, however, should be construed broadly to include semiconductor devices having other orientations. Unless stated otherwise, terms such as “first” and “second” are used to arbitrarily distinguish between the elements such terms describe. Thus, these terms are not necessarily intended to indicate temporal or other prioritization of such elements.

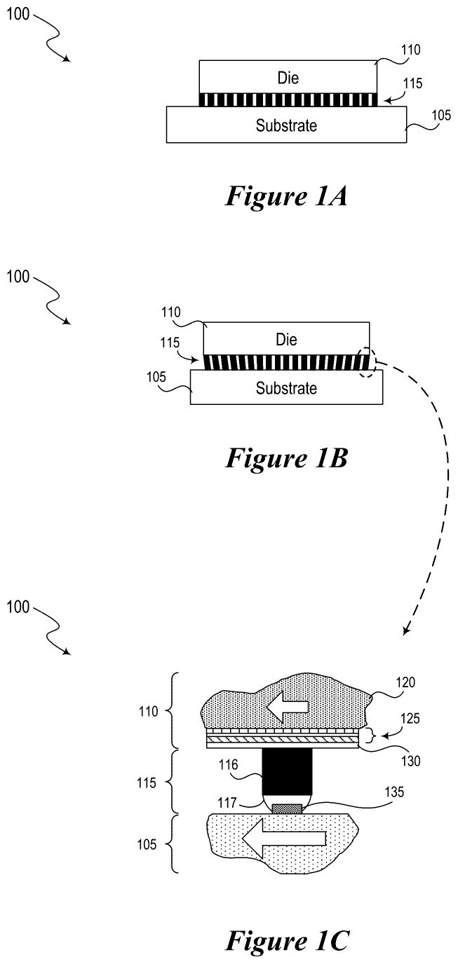

FIG. 1A illustrates a schematic cross-sectional diagram of a semiconductor die assembly 100 at an elevated temperature—e.g., during a reflow process at approximately 200° C. or higher during the DCA assembly process. The semiconductor die assembly 100 includes a semiconductor die 110 directly attached (e.g., flip-chip attached) to a package substrate 105 by forming interconnects 115 (e.g., forming joints 115) between the semiconductor die 110 and the package substrate 105. At the elevated temperature (e.g., during the reflow process), the interconnects 115 may experience relatively low stress as solder structures of the interconnects 115 exhibit low modulus values at the elevated temperature.

FIG. 1B illustrates a schematic cross-sectional diagram of the semiconductor die assembly 100 after a cool-down process following the reflow process—e.g., the semiconductor die assembly 100 at room temperature. During the cool-down process, the semiconductor die assembly 100 tends to develop stress exerted on the interconnects 115—e.g., due to the CTE mismatch between the package substrate 105 and the semiconductor die 110. For example, the CTE of package substrate 105 is greater than the CTE of the semiconductor die 110 such that the package substrate 105 shrinks more than the semiconductor die 110. As such, the interconnects 115 can be subject to the stress due to the greater shrinkage present in the package substrate 105 than the semiconductor die 110—e.g., flexural stress, peel stress. As illustrated in FIG. 1B, the interconnects 115 near the edge of the package substrate 105 may experience more stress than the interconnects 115 near the center of the package substrate 105 as indicated with slanted (tilted) interconnects 115 near the edge of the package substrate 105.

FIG. 1C illustrates a portion of the semiconductor die assembly 100 after the cool-down process depicting more details of the package substrate 105, the semiconductor die 110, and the interconnects 115. The package substrate 105 includes substrate bond pads 135 (one of which is illustrated in FIG. 1C). The semiconductor die 110 includes a semiconductor substrate 120 including circuitry 125 (e.g., metal oxide semiconductor (MOS) circuits, multi-layers of conductive traces and vias, one or more dielectric layers including various dielectric materials). Further, the circuitry 125 is connected to bond pads 130, one of which is schematically depicted in contact with the circuitry 125 in FIG. 1C.

The interconnect 115 includes a conductive section 116 (e.g., connected to the bond pad 130) and a solder section 117 (which may also be referred to as a solder connector or a solder structure). In some embodiments, the conductive section 116 includes metallic materials (e.g., copper) with relatively high modulus values. As such, the conductive section 116 tends to remain stiff during the assembly process (e.g., during the reflow process steps). In some embodiments, the solder section 117 includes a tin-based alloy (e.g., SnAg). The solder section 117 tends to exhibit relatively low melting points (e.g., melting at a lower temperature than the conductive section 116) such that the solder section 117 can melt during the reflow process to provide physical and electrical connection between the conductive section 116 (hence the interconnect 115 connected to the bond pad 130) and the substrate bond pad 135.

During the cool-down process, as the package substrate 105 may experience more shrinkage when compared to the semiconductor die 110—e.g., due to the mismatch in CTEs rendering the package substrate 105 to experience a greater lateral movement (indicated as a larger arrow in the package substrate 105) than that (indicated as a smaller arrow in the semiconductor die 110) of the semiconductor die 110. As a result of different lateral movements between the package substrate 105 and the semiconductor die 110, the interconnect 115 may experience stress (peeling stress, flexural stress). In this regard, the different lateral movements may cause the force to be exerted upon the interconnect 115.

The interconnect 115, which is connected to the circuitry 125 through the bond pad 130, may transfer the stress to the circuitry 125 of the semiconductor die 110. In some cases, the circuitry 125 may tear apart (or crack) from the semiconductor die 110 resulting in non-functional semiconductor die 110 (and non-functional semiconductor die assembly 100). Even if catastrophic physical failures of the interconnects 115 (or the circuitry 125) may not occur after the assembly process, the stress present at the interconnects 115 may become exacerbated rendering the semiconductor die assembly 100 subject to various reliability issues during the lifetime of the semiconductor die assembly 100 as the semiconductor die assembly 100 is likely to experience additional thermal and mechanical stress under normal operating conditions.

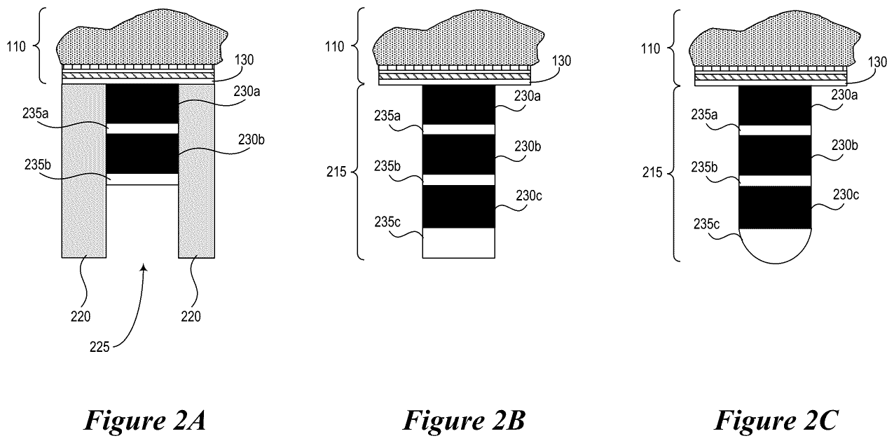

FIGS. 2A through 2C illustrate stages of a process for forming flexible interconnects in accordance with embodiments of the present technology. FIG. 2A depicts a masking layer 220 formed on the semiconductor die 110. The masking layer 220 includes a set of openings 225 (one of which is illustrated in FIG. 2A) corresponding to a set of bond pads 130 of the semiconductor die 110. The masking layer 220 may be formed using a photoresist material, a dielectric material, or a suitable material that can be used to define the set of openings 225 for forming the flexible interconnects. FIG. 2A further depicts, within the opening 225, a first rigid section 230a formed on the bond pad 130, a first flexible section 235a formed on the first rigid section 230a, a second rigid section 230b formed on the first flexible section 235a, and a second flexible section 235b formed on the second rigid section 230b.

In some embodiments, materials forming the rigid sections 230 include metals (e.g., copper, tungsten, aluminum). Such materials have relatively high modulus values (e.g., modulus values greater than those of the flexible sections 235) such that they remain relatively rigid at an elevated temperature (e.g., during the reflow process steps). In some embodiments, materials forming the flexible sections 235 include alloys with relatively low modulus values (e.g., modulus values less than those of the rigid sections 230) such that they become relatively flexible at an elevated temperature (e.g., during the reflow process steps). In some embodiments, the alloys include tin (Sn)—e.g., SnAg alloy. In further embodiments, the alloys may be doped with indium (In) or bismuth (Bi) to modulate (e.g., increase, decrease) the modulus values (or the melting temperatures). In some embodiments, the materials forming the flexible sections 235 include tin (Sn) doped with silver (Ag) or mismuth (Bi).

In some embodiments, successive plating process steps are used to form the alternating structure of rigid sections 230 and flexible sections 235. For example, copper may be selectively plated on the surface of the bond pad 130 through the opening 225 of the masking layer 220. Subsequently, SnAg alloy may be selectively plated on the surface of the copper (e.g., the surface of the first rigid section 230a) through the opening 225 of the masking layer 220. In this manner, any desired quantities of the rigid sections 230 and the flexible sections 235 can be formed through the opening 225 of the masking layer 220. Upon completing the plating process steps, the masking layer 220 can be removed.

FIG. 2B depicts that a conductive pillar 215 is formed on the bond pad 130 of the semiconductor die 110—e.g., utilizing the successive plating process steps. Further, the masking layer 220 is removed from the semiconductor die 110 after forming the last flexible section 235c. The conductive pillar 215 includes three rigid sections 230 (also identified individually as rigid sections 230a-c) and three flexible sections 235 (also identified individually as flexible sections 235a-c) interspersed throughout the conductive pillar 215. The last flexible section 235 (e.g., the flexible section 235c) may be configured to attach to a substrate bond pad (e.g., the substrate bond pad 130) of a package substrate (e.g., the package substrate 105). As such, the last flexible section 235 may be referred to as a solder structure or a solder section.

FIG. 2C depicts the conductive pillar 215 after a pillar reflow process step. During the pillar reflow process, the semiconductor die 110 including the conductive pillars 215 brought to an elevated temperature above the solder liquidus temperature (e.g., 220-260° C.). As a result of the pillar reflow process, the last flexible section (e.g., the flexible section 235c, the solder structure for the conductive pillar) may become rounded as the last flexible section with low modulus at the elevated temperature tends to reflow to reduce its surface area.

In some embodiments, the conductive pillars 215 (also the openings 225) have a diameter of approximately 50 micrometers (μm) or less—e.g., 50 μm, 40 μm, 30 μm, or so. In other embodiments, the conductive pillar 215 has a diameter of greater than 50 micrometers (μm)—e.g., 60 μm, 70 μm or so. In some embodiments, the rigid sections 230 are approximately 5 to 10 μm thick. In some embodiments, the flexible sections 235 are approximately 2 to 5 μm thick. The last flexible section 235 (e.g., the flexible section 235c) may be thicker than other flexible sections 235 (e.g., the flexible sections 235-a or 235-b). In some embodiments, the rigid sections 230 have approximately same thicknesses. In other embodiments, the rigid sections 230 have different thickness from each other. In some embodiments, the flexible sections 235 have approximately same melting temperatures. In other embodiments, the flexible sections 235 have different melting temperatures. For example, the flexible section 235c may have a lower melting point than the flexible section 235-a, the flexible section 235-b, or both.

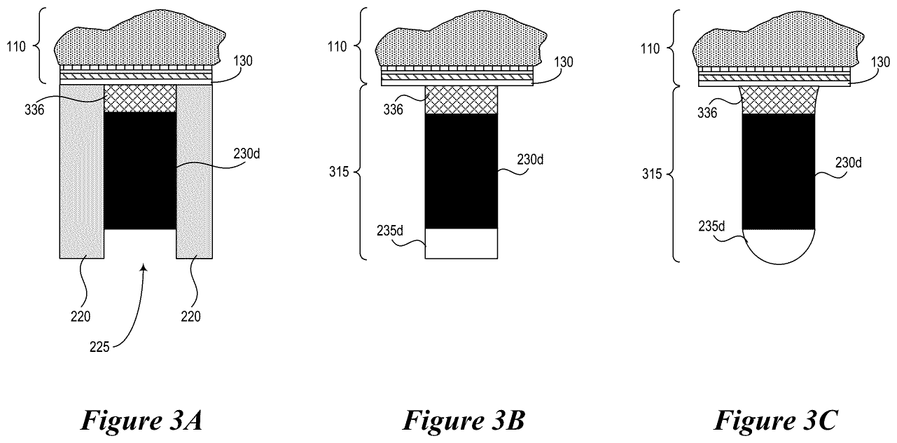

Although the foregoing example process described with reference to FIGS. 2A through 2C illustrates one of the rigid section 230 (e.g., the rigid section 230a) of the conductive pillar 215 formed on the bond pad 130, the present technology is not limited thereto. For example, a flexible section can be formed on the bond pad prior to forming a rigid section of the conductive pillar. FIGS. 3A through 3C illustrate stages of such a process forming flexible interconnects in accordance with embodiments of the present technology. FIG. 3A depicts the masking layer 220 described with reference to FIG. 2A formed on the semiconductor die 110. The masking layer 220 also includes the set of openings 225 (one of which is illustrated in FIG. 3A) corresponding to the set of bond pads 130 of the semiconductor die 110. FIG. 3A further depicts, within the opening 225, a flexible section 336 formed on the bond pad 130 and a rigid section 230d formed on the flexible section 336. Subsequently, another flexible section 235d (e.g., a solder structure) can be formed on the rigid section 230d.

After forming the flexible section 235d through the opening 225, the masking layer 220 can be removed as shown in the conductive pillar 315 depicted in FIG. 3B. In this manner, the conductive pillar 315 includes the flexible section 336 disposed between the bond pad 130 and the rigid section 230d. FIG. 3C depicts the conductive pillar 315 after the pillar reflow process step making the last flexible section 235d relatively round (the solder structure for the conductive pillar 315). In some embodiments, the flexible section 336 includes the materials described above with reference to the flexible sections 235—e.g., Sn doped with In and/or Bi, SnAg alloy including dopants (In, Bi, etc.). In some embodiments, the flexible section 236 includes a material with a melting temperature greater than that of the flexible section 235d. In this manner, the rigid section 230d can remain connected to the bond pad 130 during the pillar reflow process (or during the mass reflow process). Although the conductive pillar 315 is depicted to include a single rigid section 230d, the present technology is not limited thereto. For example, the conductive pillar 315 may include two or more rigid sections similar to the conductive pillar 215 described with reference to FIG. 2C.

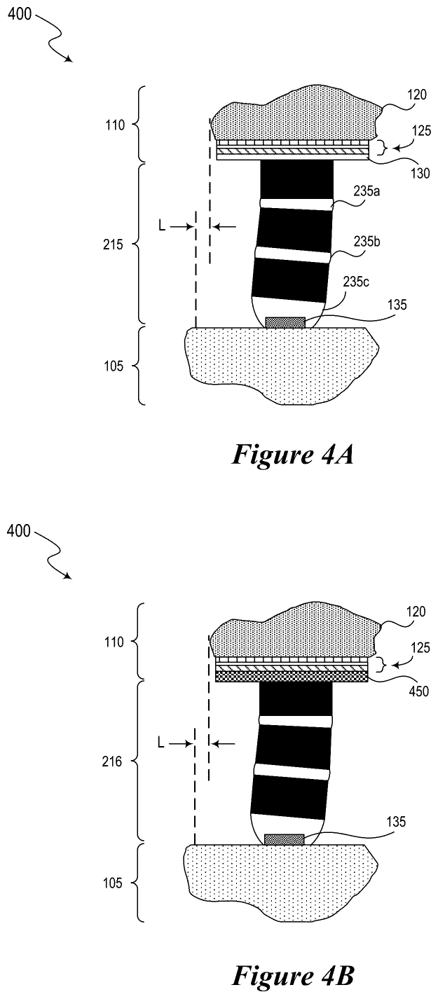

FIGS. 4A and 4B illustrate schematic diagrams of a semiconductor die assembly 400 in accordance with embodiments of the present technology. In particular, FIG. 4A depicts one of the conductive pillars of the semiconductor die 110 (e.g., the conductive pillar 215 described with reference to FIG. 2C) attached to a corresponding substrate bond pad 135 of the package substrate 105 after the reflow process has been completed. In this regard, the conductive pillars 215 are aligned to corresponding substrate bond pads 135 such that the flexible sections 235c of the conductive pillars 215 are in contact with the substrate bond pads 135. Subsequently, the flexible sections 235c melt during the reflow process steps to bond (attach) the flexible sections 235c (hence the conductive pillars 215 connected to the bond pad 130) with the corresponding substrate bond pads 135.

During the reflow process, the conductive pillar 215 may have been straight as shown in FIG. 2C without the bend (curvature) depicted in FIG. 4A. While the semiconductor die 110 and the package substrate 105 cool down after the reflow process, however, the package substrate 105 may experience more shrinkage than the semiconductor die 110 due to the CTE mismatch. As a result of the package substrate 105 shrinking more than the semiconductor die 110, a greater lateral displacement of the substrate bond pad 135 may occur with respect to the conductive pillar 215 connected to the bond pad 130 (as denoted as L in FIG. 4A). The greater lateral displacement of the substrate bond pad 135 may exert force to the conductive pillar 215.

As the conductive pillars 215 comprises multiple flexible sections 235 (e.g., flexible section 235a, flexible section 235b) including malleable materials (e.g., TnAg alloy) at the reflow temperature (or at least part of the cool down process), the conductive pillars 215 may bend (or deform) to release (or accommodate) stress developed in the conductive pillars 215 or various interfaces associated with the conductive pillars 215—e.g., between the conductive pillar 215 and the bond pad 130, between the bond pad 130 and the circuitry 125, between the layers of the circuitry 125. In this manner, the semiconductor die assembly 400 including the conductive pillars 215 is expected to be less prone to the yield and reliability issues associated with the stress during the assembly process.

Moreover, the conductive pillars with flexible sections may be used as mechanical pillars for the semiconductor die assembly 400. Mechanical pillars (interconnects, joints) can provide additional bonding strength between the semiconductor die 110 and the package substrate 105—e.g., in addition to the bonding strength provided by the conductive pillars 215. In some embodiments, the mechanical pillars are formed on a layer 450 of the semiconductor die 110, which is configured to have low stiffness (e.g., polyimide layer) to provide resilience against the stress. As such, the mechanical pillars may be electrically isolated from the circuitry 125. FIG. 4B depicts one of such mechanical pillars 216 of the semiconductor die 110 attached to a corresponding substrate bond pad 135 of the package substrate 105 after the reflow process. As described above with reference to FIG. 4A, the mechanical pillar 216 may bend in response to the stress during the assembly process—e.g., flexural stress developed during the cool-down process.

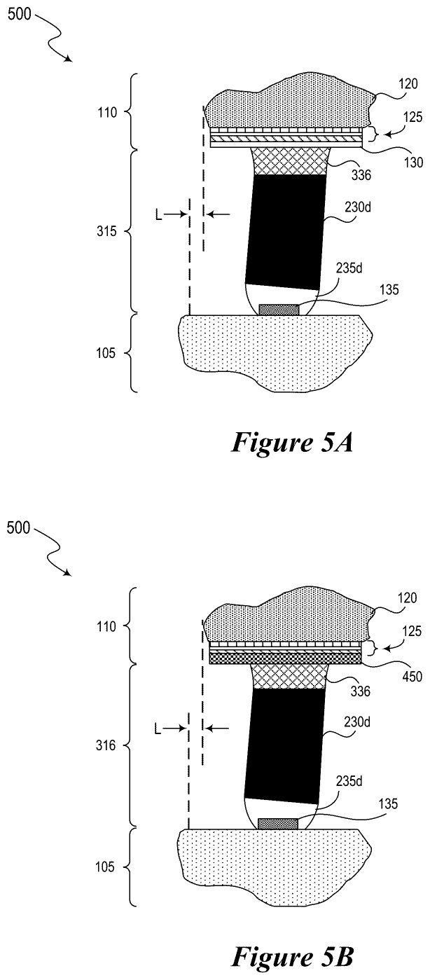

FIGS. 5A and 5B illustrate schematic diagrams of a semiconductor die assembly 500 in accordance with embodiments of the present technology. In particular, FIG. 5A depicts one of the conductive pillars of the semiconductor die 110 (e.g., the conductive pillar 315 described with reference to FIG. 3C) attached to a corresponding substrate bond pad 135 of the package substrate 105 after the reflow process. As described above with reference to FIG. 4A, the conductive pillar 315 may bend (deform) in response to the stress during the assembly process—e.g., during the cool-down process steps. FIG. 5B illustrates the conductive pillar with flexible sections used as a mechanical pillar. As such, the mechanical pillar 316 may be electrically isolated from the bond pad 130 and can be formed on the layer 450 (with low stiffness, e.g., polyimide layer) of the semiconductor die 110.

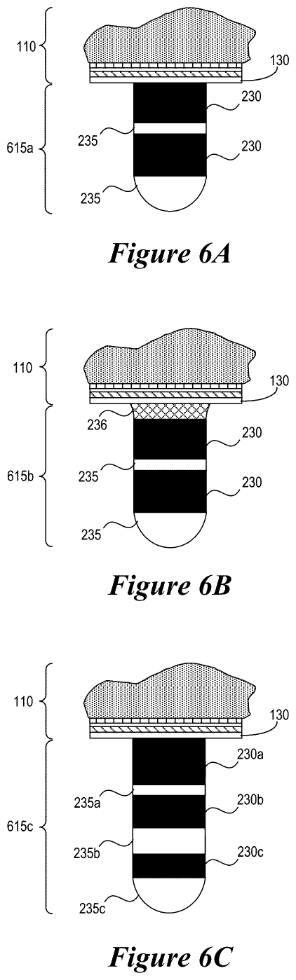

FIGS. 6A through 6C illustrate schematic diagrams of flexible interconnects in accordance with embodiments of the present technology. FIG. 6A depicts a conductive pillar 615a with a rigid section 230 in contact with the bond pad 130 of the semiconductor die 110. The conductive pillar 615a may be regarded as a variation of the conductive pillar 215—e.g., including two rigid sections 230 instead of the three rigid sections 230 of the conductive pillar 215.

FIG. 6B depicts a conductive pillar 615b, which may be regarded as a variation of the conductive pillar 615a—e.g., including a flexible section in contact with the bond pad 130. Further, the conductive pillar 615b may be regarded as a variation of the conductive pillar 315—e.g., including two rigid sections 230 instead of the single rigid section 230d of the conductive pillar 315.

Although some of the foregoing example conductive pillars of FIGS. 2A through 6B include rigid sections with similar thicknesses (e.g., rigid sections 230a-c) and flexible sections with similar thicknesses (e.g., flexible sections 235a/b), the present technology is not limited thereto. FIG. 6C depicts a conductive pillar 615c with multiple rigid sections 230 with different thicknesses and multiple flexible sections 235 with different thicknesses. Further, the conductive pillars 615a-c can be used as mechanical pillars as described with reference to FIGS. 4B and 5B.

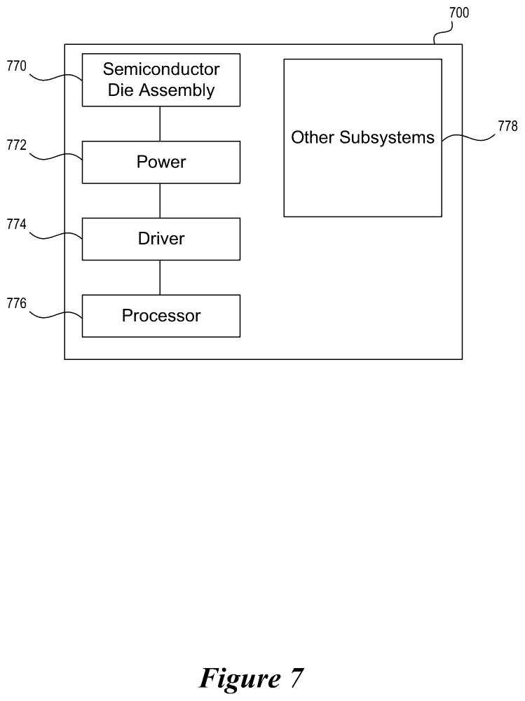

FIG. 7 is a block diagram schematically illustrating a system 700 including a semiconductor die assembly in accordance with embodiments of the present technology. The system 700 can include a semiconductor device assembly 770, a power source 772, a driver 774, a processor 776, and/or other subsystems or components 778. The semiconductor die assembly 200, 201, 300, or 301 described with reference to FIGS. 2A through 6D may be included in the semiconductor device assembly 770 of the system 700.

The semiconductor device assembly 770 can have features generally similar to the semiconductor die assembly 400 and 500. For example, the semiconductor device assembly 770 includes a package substrate including a plurality of substrate bond pads, and a semiconductor die attached to the package substrate. The semiconductor die includes semiconductor substrate having circuitry, a plurality of bond pads coupled to the circuitry, each one of the bond pads of the plurality attached to a conductive pillar having a rigid section with a first side facing the bond pad and a second side opposite to the first side, a first flexible section connected to the first side of the rigid section, and a second flexible section connected to the second side of the rigid section, wherein the second flexible section of each conductive pillar is attached to a corresponding substrate bond pad of the plurality. In some embodiments, the first flexible section of each conductive pillar is further attached to a corresponding bond pad of the plurality such that the first flexible section is located between the bond pad and the first side of the rigid section. In some embodiments, the rigid section comprises copper, the first flexible section comprises a first solder material with a first melting temperature, and the second flexible section comprises a second solder material with a second melting temperature less than the first melting temperature.

In some embodiments, the rigid section is a first rigid section of the conductive pillar, and the conductive pillar further comprises a second rigid section connected to the first flexible section such that the first flexible section is located between the first and second rigid sections. In some embodiments, the second rigid section includes a third side connected to the bond pad, and the second rigid section is connected to the first flexible section at a fourth side of the second rigid section opposite to the third side.

The resulting system 700 can perform any of a wide variety of functions, such as memory storage, data processing, and/or other suitable functions. Accordingly, representative systems 700 can include, without limitation, hand-held devices (e.g., mobile phones, tablets, digital readers, and digital audio players), computers, and appliances. Components of the system 700 may be housed in a single unit or distributed over multiple, interconnected units (e.g., through a communications network). The components of the system 700 can also include remote devices and any of a wide variety of computer readable media.

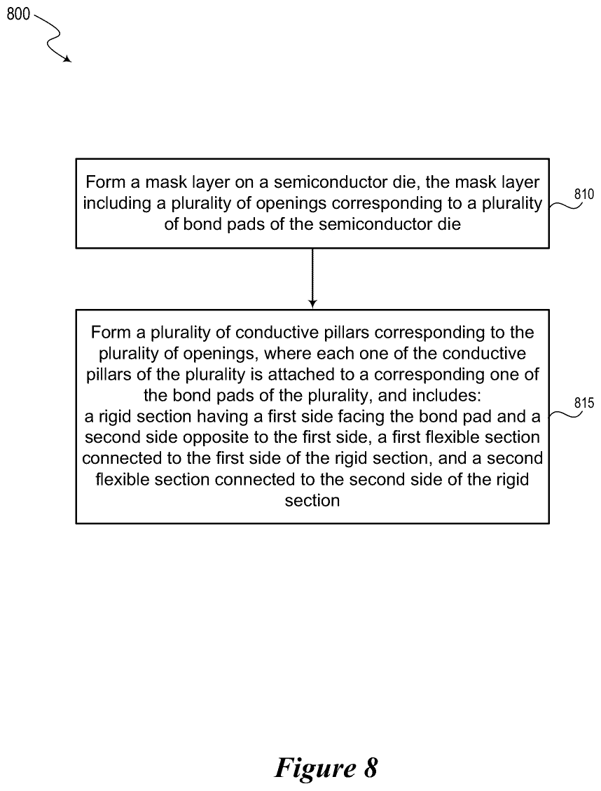

FIG. 8 is a flowchart 800 of a method of forming a semiconductor device assembly in accordance with embodiments of the present technology. The flowchart 800 may include aspects of methods as described with reference to FIGS. 2A through 6C.

The method includes forming a mask layer on a semiconductor die, the mask layer including a plurality of openings corresponding to a plurality of bond pads of the semiconductor die (box 810). The method further includes forming a plurality of conductive pillars corresponding to the plurality of openings, where each one of the conductive pillars of the plurality is attached to a corresponding one of the bond pads of the plurality, and includes a rigid section having a first side facing the bond pad and a second side opposite to the first side, a first flexible section connected to the first side of the rigid section, and a second flexible section connected to the second side of the rigid section (box 815).

In some embodiments, forming the plurality of conductive pillars comprises plating a first solder material corresponding to the first flexible section on the plurality of bond pads through the plurality of openings, plating copper corresponding to the rigid section on the first solder material through the plurality of openings, and plating a second solder material corresponding to the second flexible section on the copper through the plurality of openings.

In some embodiments, the method further includes removing the mask layer after plating the second solder material, and attaching the semiconductor die to a package substate such that the second flexible sections of individual conductive pillars of the semiconductor die are attached to corresponding substrate bond pads of the package substrate. In some embodiments, the rigid section is a first rigid section of the conductive pillar, and the method further comprises forming, prior to forming the first flexible section, the first rigid section, and the second flexible section, a second rigid section of the conductive pillar such that a first side of the second rigid section is connected to the bond pad and a second side of the second rigid section opposite to the first side is connected to the first flexible section such that the first flexible section is located between the first and second rigid sections.

In some embodiments, forming the plurality of conductive pillars comprises plating first copper corresponding to the second rigid section on the plurality of bond pads through the plurality of openings, plating a first solder material corresponding to the first flexible section on the first copper through the plurality of openings, plating second copper corresponding to the first rigid section on the first solder material through the plurality of openings, and plating a second solder material corresponding to the second flexible section on the second copper through the plurality of openings.

It should be noted that the methods described above describe possible implementations, and that the operations and the steps may be rearranged or otherwise modified and that other implementations are possible. Furthermore, embodiments from two or more of the methods may be combined. From the foregoing, it will be appreciated that specific embodiments of the technology have been described herein for purposes of illustration, but that various modifications may be made without deviating from the disclosure. In addition, while in the illustrated embodiments certain features or components have been shown as having certain arrangements or configurations, other arrangements and configurations are possible. Moreover, certain aspects of the present technology described in the context of particular embodiments may also be combined or eliminated in other embodiments.

The devices discussed herein, including a semiconductor device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.” The term “exemplary” used herein means “serving as an example, instance, or illustration,” and not “preferred” or “advantageous over other examples.”

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor die, comprising:
a semiconductor substrate including circuitry;
a plurality of bond pads coupled to the circuitry, each one of the bond pads of the plurality attached to a conductive pillar including:
a rigid section having a first side facing the bond pad and a second side opposite to the first side;
a first flexible section directly connected to the first side of the rigid section and directly connected to the bond pad; and
a second flexible section connected to the second side of the rigid section, wherein the first flexible section and the second flexible section are each configured to deform in response to less force than the rigid section.

2. The semiconductor die of claim 1, wherein:
the rigid section includes a first material having a first modulus value;
the first flexible section includes a second material having a second modulus value;
the second flexible section includes a third material having a third modulus value, wherein the first modulus value is greater than the second modulus value or the third modulus value.

3. The semiconductor die of claim 1, wherein:
the first flexible section is further connected to the bond pad such that the first flexible section is located between the bond pad and the first side of the rigid section; and
the second flexible section is configured to attach to a substrate bond pad of a package substrate.

4. The semiconductor die of claim 3, wherein:
the rigid section comprises copper;
the first flexible section comprises a first solder material with a first melting temperature; and
the second flexible section comprises a second solder material with a second melting temperature less than the first melting temperature.

5. The semiconductor die of claim 1, wherein the rigid section is a first rigid section of the conductive pillar, and the conductive pillar further comprises a second rigid section connected to the first flexible section such that the first flexible section is located between the first and second rigid sections.

6. The semiconductor die of claim 5, wherein:
the second rigid section includes a third side connected to the bond pad; and
the second rigid section is connected to the first flexible section at a fourth side of the second rigid section opposite to the third side.

7. The semiconductor die of claim 6, wherein the second flexible section is configured to attach to a substrate bond pad of a package substrate.

8. The semiconductor die of claim 6, wherein:
the first and second rigid sections comprise copper; and
the first and second flexible sections comprise a solder material.

9. The semiconductor die of claim 5, wherein the conductive pillar further comprises a third rigid section connected to the second flexible section such that the second flexible section is located between the first and third rigid sections.

10. The semiconductor die of claim 9, wherein:
the third rigid section includes a fifth side connected to the second flexible section; and
the third rigid section is connected to a third flexible section of the conductive pillar at a sixth side of the third rigid section opposite to the fifth side, the third flexible section configured to attach to a substrate bond pad of a package substrate.

11. The semiconductor die of claim 10, wherein:
the first, second, and third rigid sections comprise copper; and
the first, second, and third flexible sections comprise a solder material.

12. A method, comprising:
forming a mask layer on a semiconductor die, the mask layer including a plurality of openings corresponding to a plurality of bond pads of the semiconductor die; and
forming a plurality of conductive pillars corresponding to the plurality of openings, wherein each one of the conductive pillars of the plurality is attached to a corresponding one of the bond pads of the plurality, and includes:
a rigid section having a first side facing the bond pad and a second side opposite to the first side;
a first flexible section connected to the first side of the rigid section; and
a second flexible section connected to the second side of the rigid section.

13. The method of claim 12, wherein forming the plurality of conductive pillars comprises:
plating a first solder material corresponding to the first flexible section on the plurality of bond pads through the plurality of openings;
plating copper corresponding to the rigid section on the first solder material through the plurality of openings; and
plating a second solder material corresponding to the second flexible section on the copper through the plurality of openings.

14. The method of claim 12, wherein the rigid section is a first rigid section of the conductive pillar, and the method further comprises:
forming, prior to forming the first flexible section, the first rigid section, and the second flexible section, a second rigid section of the conductive pillar such that a first side of the second rigid section is connected to the bond pad and a second side of the second rigid section opposite to the first side is connected to the first flexible section such that the first flexible section is located between the first and second rigid sections.

15. The method of claim 14, wherein forming the plurality of conductive pillars comprises:
plating first copper corresponding to the second rigid section on the plurality of bond pads through the plurality of openings;
plating a first solder material corresponding to the first flexible section on the first copper through the plurality of openings;
plating second copper corresponding to the first rigid section on the first solder material through the plurality of openings; and
plating a second solder material corresponding to the second flexible section on the second copper through the plurality of openings.

16. A semiconductor die assembly, comprising:
a package substrate including a plurality of substrate bond pads; and
a semiconductor die attached to the package substrate, the semiconductor die including:
a semiconductor substrate having circuitry;
a plurality of bond pads coupled to the circuitry, each one of the bond pads of the plurality attached to a conductive pillar having:
a rigid section with a first side facing the bond pad and a second side opposite to the first side;
a first flexible section directly connected to the first side of the rigid section and directly connected to the bond pad; and
a second flexible section connected to the second side of the rigid section, wherein the second flexible section of each conductive pillar is attached to a corresponding substrate bond pad of the plurality.

17. The semiconductor die assembly of claim 16, wherein the first flexible section of each conductive pillar is further attached to a corresponding bond pad of the plurality such that the first flexible section is located between the bond pad and the first side of the rigid section.

18. The semiconductor die assembly of claim 16, wherein:
the rigid section comprises copper;
the first flexible section comprises a first solder material with a first melting temperature; and
the second flexible section comprises a second solder material with a second melting temperature less than the first melting temperature.

19. The semiconductor die assembly of claim 16, wherein the rigid section is a first rigid section of the conductive pillar, and the conductive pillar further comprises a second rigid section connected to the first flexible section such that the first flexible section is located between the first and second rigid sections.

20. The semiconductor die of claim 19, wherein:
the second rigid section includes a third side connected to the bond pad; and
the second rigid section is connected to the first flexible section at a fourth side of the second rigid section opposite to the third side.
